(19) United States
(12) Patent Application Publication
(10) Pub. No.: US 2002/0194568 A1
(43) Pub. Date: Dec. 19, 2002

(54) Error correcting method, disk medium, disk recording method and disk reproducing method

(76) Inventors: Yoshiharu Kobayashi, Osaka (JP); Junichi Minamino, Nara (JP); Atsushi Nakamura, Osaka (JP)

Correspondence Address: Neil A Duchez, Renner Otto Boisselle & Sklar, 1621 Euclid Avenue 19th Floor, Cleveland, OH, 44115, US

(21) Appl. No.: 10/169,646

(22) PCT Filed: Dec. 20, 2000
(86) PCT No.: PCT/JP00/09059

(30) Foreign Application Priority Data
Jan. 7, 2000 (JP) 2000/1215

(51) Int. Cl. G11C 29/00

(52) U.S. Cl. 714/763

(57) ABSTRACT

The disk medium 200 of the present invention includes a sector group 3 including a plurality of positionally continuous sectors 2 in which address information including at least address data and parity data is dispersedly provided in the plurality of sectors of the sector group in a prescribed unit. The address information includes an information sequence described by a combination of at least “0”, “1” and an identification mark 4, the identification mark is provided at the head of the sector group, the address data includes data bits, and the parity data includes parity bits. With this structure, it is possible to realize small address redundancy and high reliability of address reproduction.

### TECHNICAL FIELD

The present invention relates to a digital information recording medium (a disk medium), a disk medium address error correcting scheme, and a disk recording/reproducing method using the error correcting scheme.

### BACKGROUND ART

Recently, recordable optical disks have been entering the marketplace. In general, a recordable optical disk has a random access ability, i.e., an ability to perform a recording/reproducing operation for a sector unit, which is a unit of a data group, in an arbitrary order. An element essential to this random access ability is an address which indicates a sector. By reading an address allocated to a sector so as to recognize a sector to/from which information is recorded/reproduced when performing a recording/reproducing operation, it is possible to perform a recording/reproducing operation on a designated sector.

High reliability is required for this address reproduction. When the reliability of the address reproduction is low, for example, there is a possibility that an address is erroneously recognized, so that critical malfunction occurs, e.g., data is written in a wrong sector and data originally recorded in that sector is damaged, and so on. Therefore, the reliability of address reproduction is essential to the recordable optical disk, and thus a variety of methods are suggested for securing sufficient reliability of address reproduction.

FIG. 15 illustrates an address format of a 2.6 GB-DVD-RAM which is an example of a conventional optical disk (Yoshihito KAKUDA, et al., Nikkei Electronics, Oct. 6, 1997, “A whole picture of a DVD-RAM standard, detailed account by a planner (first volume)”, Oct. 20, 1997, “A whole picture of a DVD-RAM Standard, detailed account by a planner (second volume)”).

The upper part of FIG. 15 shows a structure of a top surface of a disk medium including sectors 2. Address information 10 is recorded at the lead of each sector 2, and therefore a part of each sector 2 following the address information 10 can be identified.

The middle part of FIG. 15 shows a format of each sector 2. One sector includes information of 2697 bytes in total: from the front, a header part 128 bytes; a mirror mark part 5 bytes; a gap part 17 bytes; VFO 50 bytes; recorded data 2418 bytes; guard data 30 bytes; and a buffer 49 bytes. Among these parts, the address information 10 is stored in the header part. In general, this header part includes concave and convex portions, i.e., information is recorded by embossing, and therefore only a read operation is possible. Accordingly, an address represented by this address information is referred to as a PID (physical ID) or a physical address since the address indicates a physical position on a disk medium.

The lower part of FIG. 15 illustrates a data format of a header part, i.e., address information of each sector 2. In this example, four pieces of PID information are arranged. The four pieces of PID information include 46 bytes: VFO 36 bytes; AM 3 bytes; PID 4 bytes; IED 2 bytes; and PA 1 byte. These four pieces of PID information are reproduced so as to recognize a single sector, thereby securing the reliability required for address reproduction.

However, there is a demand for higher recording density. As the recording density is increased, the number of addresses in a disk is increased. Along with this, the reliability of address reproduction is reduced, and therefore redundancy in an address part is required to be increased so as to compensate for such a reduction in address reproduction reliability.

In the example shown in FIG. 15, 128 bytes out of 2697 bytes of sector capacity are allocated to a header part, i.e., address information. In other words, in order to obtain the reliability required for address reproduction, four pieces of PID are recorded in a single sector so as to provide large redundancy for securing the reliability of the address reproduction. The quantity of data stored in the address part occupies about 5% of the quantity of data stored in an entire sector, which is an obstacle to improvement in recording density.

The present invention is made in consideration of the circumstances described above, and an objective thereof is to provide a disk medium having high reliability of address reproduction in spite of small redundancy, an error correcting scheme, a disk recording method, and a disk reproducing method.

### DISCLOSURE OF THE INVENTION

In an error correcting scheme of the present invention, when an error correcting code includes twenty data bits, seven parity bits as a burst error correction code for the data bits and five parity bits as a random error correction code for the data bits, the number of burst error correction bits of the burst error correction code is three and the number of random error correction bits of the random error correction code is one, a combination of a syndrome of the burst error correction code and a syndrome of the random error correction code is unique to each of 1-bit errors, 2-bit errors and 3-bit burst error and error correction is performed based on the syndrome of the burst error correction code and the syndrome of the random error correction code, thereby achieving the above-described objective.

A disk medium of the present invention includes a sector group including a plurality of positionally continuous sectors in which address information including at least address data and parity data is dispersedly provided in the plurality of sectors of the sector group in a prescribed unit, the address information including an information sequence described by a combination of at least 0, 1 and an identification mark, the identification mark being provided at the head of the sector group, the address data including data bits, and the parity data including parity bits, thereby achieving the above-described objective.

In one embodiment of the invention, a length of the sector group is preferably shorter than one track length.

In one embodiment of the invention, an integral number of the sector groups are set so as to be a unit of information to be recorded or reproduced.

In one embodiment of the invention, the address information is dispersedly provided in the plurality of sectors of the sector group by one code alphabet.

In one embodiment of the invention, in the address information, the address data is positioned so as to follow the identification mark and the address data includes a LSB.

In one embodiment of the invention, in the address information, the parity data is positioned so as to follow the identification mark, the address data is positioned after the parity data, and the address data includes the LSB.

In one embodiment of the invention, the disk medium has a capacity of 235 bytes of lower, one sector includes 2¹¹ byte-data, the sector group includes thirty two sectors, and the address information is configured so as to include a 1-bit identification mark, 19-bit address data, 7-bit parity data of the burst error correction code for the address data, and 5-bit parity data of the random error correction code for the address data.

In one embodiment of the invention, the disk medium has a capacity of 236 bytes of lower, one sector includes 2¹¹ byte-data, the sector group includes thirty two sectors, the address information is configured so as to include a 1-bit identification mark, 19-bit address data, 7-bit parity data of the burst error correction code for the address data, and 5-bit parity data of the random error correction code for the address data, and the 1-bit identification mark can be selected from two types of identification marks.

According to a disk reproducing method of the present invention, in the above-described disk medium, after reproducing address information of a prescribed and specific sector group, a track jump over one track is performed so as to reproduce the address information of the prescribed and specific sector group from the lead thereof, thereby achieving the above-described objective.

In one embodiment of the invention, detection of the identification mark starts acquisition of the address information.

In one embodiment of the invention, detection of the identification mark starts a data recording operation or data reproducing operation.

In one embodiment of the invention, error detection or error correction is performed on reproduced address information and a recording/reproducing operation is performed on the sector group represented by the address information based on a result of the error detection or error correction.

In one embodiment of the invention, when it is detected that a size of an envelope of a reproduced signal representing bits in reproduced address information are not in a prescribed range or it is detected, based on the reproduced signal representing the bits in the address information, that relative positions of a head and a track are not in a prescribed range, reproduced data bits corresponding to the bits in the reproduced address information can be used as erasure bits so as to perform an erasure correction.

In one embodiment of the invention, burst error correction is performed on reproduced data of the address information.

In one embodiment of the invention, random error correction is performed on reproduced data of the address information.

In one embodiment of the invention, burst error correction or random error correction is performed on reproduced data of the address information.

In one embodiment of the invention, a part of the address information is reproduced so as to detect that a sector group being reproduced is not an expected sector group.

According to a disk recording method of the present invention, in the above-described disk medium, detection of the identification mark starts a data recording operation or data reproducing operation.

In one embodiment of the invention, error detection or error correction is performed on reproduced address information and a recording/reproducing operation is performed on the sector group represented by the address information based on a result of the error detection or error correction.

In one embodiment of the invention, burst error correction is performed on reproduced data of the address information.

In one embodiment of the invention, random error correction is performed on reproduced data of the address information.

In one embodiment of the invention, burst error correction or random error correction is performed on reproduced data of the address information.

In one embodiment of the invention, a part of the address information is reproduced so as to detect that a sector group being reproduced is not an expected sector group.

### BRIEF DESCRIPTION OF THE DRAWINGS

FIG. 1 is a structural diagram of a disk medium according to the present invention.

FIGS. 2(a)-(e) are structural diagrams of address information on the disk medium of FIG. 1.

FIGS. 3(a) and 3(b) are magnified views each illustrating portions in which address information of the lead of a sector shown in FIG. 2(b) is recorded.

FIGS. 4(a)-4(d) are diagrams illustrating types of code alphabets of address information.

FIGS. 5(a)-(d) are views for describing the number of reproduction errors caused when there are flaws or stains on a disk medium.

FIG. 6(a) is a diagram illustrating an example of a format of data obtained by encoding address data on a disk medium according to an error correcting scheme of the present invention; FIG. 6(b) is a diagram illustrating an example of a table used for performing the above-described encoding operation; and FIG. 6(c) is a diagram illustrating an example of conversion from encoded address data to address information data.

FIG. 7 is a table showing syndromes with respect to error patterns of address information data.

FIG. 8 is another table showing syndromes with respect to error patterns of address information data.

FIG. 9 is a still another table showing syndromes with respect to error patterns of address information data.

FIG. 10 is a flowchart for describing a method for encoding address data, i.e., a method for generating address information, according to the error correcting scheme of the present invention.

FIG. 11 is a flowchart for describing a method for decoding address information according to the error correcting scheme of the present invention.

FIGS. 12(a)-(c) are diagrams for describing data generated during an address information decoding process according to the error correcting scheme of the present invention.

FIG. 13 is a diagram for describing a method for performing a still operation on a disk medium according to a recording/reproducing method of the present invention.

FIG. 14 is a structural diagram showing an example of a disk drive for realizing the recording/reproducing method of the present invention.

FIG. 15 is a structural diagram of a conventional disk medium.

### BEST MODE FOR CARRYING OUT THE INVENTION

A basic concept of the present invention is firstly described.

An error correcting scheme according to the present invention uses, as an error correction code, address data to which parity data is added so as to perform an error correcting operation in an address reproduction process. The parity data includes a combination of two codes, and an error detecting or correcting operation is performed on reproduced address data based on the combination of two codes. A disk recording/reproducing method according to the present invention uses such an error correcting scheme so as to read a target address.

In order to realize the error correction described above, in the disk medium according to the present invention, a plurality of positionally continuous sectors form a single sector group and address information including the above-described error correction code is dispersedly recorded in the plurality of sectors of the sector group in a predetermined unit. The address information includes at least a combination of 0, 1 and an identification mark.

Hereinafter, embodiments of the present invention are described in detail with reference to the drawings.

### EXAMPLE 1

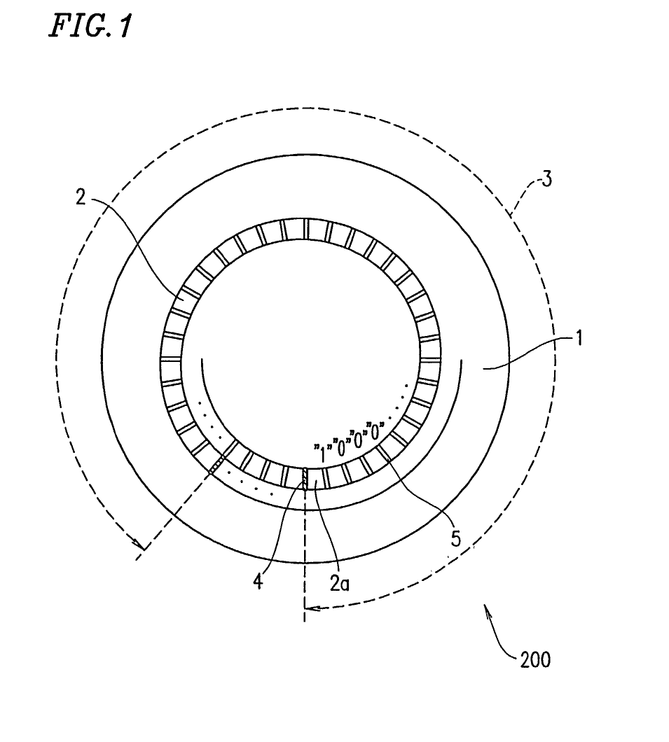

An example of a disk medium is described as Example 1. FIG. 1 is a plan view showing a structure of a top surface of a disk medium 200 according to the present invention.

Generally, data is divided into sector units so as to be recorded on a disk medium. In the disk medium 200 of the present embodiment, a plurality of positionally continuous sectors 2 form a sector group 3. In the present embodiment, a single sector group is formed of 32 sectors. An address information bit 5 of one bit is recorded in the lead of each sector. A single sector group includes one set of address information bits, i.e., address information bits of 32 bits. An identification mark 4 is recorded as an address information bit of a sector 2a at the lead of each sector group. Accordingly, the address information includes three code alphabets (a symbol used in a code sequence is referred to as the “code alphabet”) which include 0, 1 and an identification mark. In the present embodiment, a physical length of a single sector group is one track length (a length of one circuit of a track) or less.

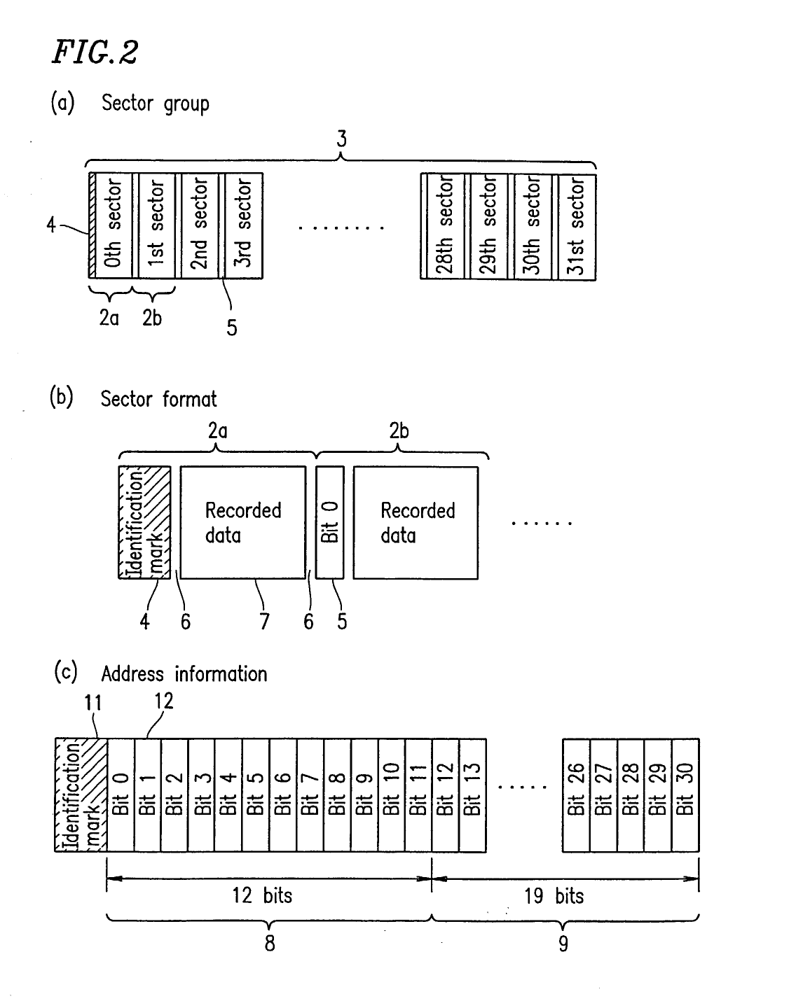

FIGS. 2(a)-2(c) each illustrates a structure of address information. FIG. 2(a) illustrates a diagram in which 32 sectors are linearly arranged so as to form a sector group 3. In this example, the sector group 3 corresponds to an ECC (error correction code) block which is a unit of information to be recorded/reproduced. That is, sectors within a range of one set of address information represent a single ECC block. Accordingly, the single ECC block is formed of 32 sectors which form a single sector group. By using this address format, it is possible to represent 219×32 sectors, and thus the address format can be applied to a disk having a capacity of up to about 34 GB when data of 2048 bytes is recorded in a single sector. Although it is described here that a single sector group corresponds to a single ECC block, this invention is applicable even in a case where a plurality (integral number) of sector groups form a single ECC. This is also said of embodiments described below.

FIG. 2(b) is a magnified view of the lead of the sector group 3 shown in FIG. 2(a). Address information is recorded in the lead of each sector. The address information includes a set of 32 information bits, the identification mark 4 recorded in the lead of a leading sector 2a of a sector group and the error correction code bits 5 dispersedly recorded such that a single error correction code bit is provided ahead of each sector of non-leading sectors 2b in a sector group. A gap 6, i.e., a region in which nothing is recorded, is provided immediately after each address information bit and a region in which recorded data 7 is recorded is provided after each gap 6. The address information is usually recorded during disk production by forming physical concaves and convexes in a disk medium, i.e., embossing the disk medium. User data formatted according to a prescribed format is recorded as the recorded data 7.

The gap 6 is again provided after the recorded data 7 so as to separate the recorded data 7 from the address information bit 5 of the next sector. These two gaps 6 are provided so as to prevent the recorded data 7 and the address information bit 5 from being recorded so as to be overlapped with each other even if a recording start position is erroneously decided.

It should be noted that a unit of data to be recorded/reproduced usually corresponds to an ECC block and therefore ECC block data is recorded from a sector including the identification mark 4, i.e., the leading sector 2a of the sector group.

FIG. 2(c) illustrates a data format of address information recorded in the disk medium 200. An identification mark bit 11 is provided in the lead of the address information and is followed by binary data including address information data bits from bit 0 to bit 30. 12-bit data from bit 0 to bit 11 is parity data 8 and 19-bit data from bit 12 to bit 30 is address data 9. It should be noted that a positional order of the parity data 8 and the address data 9 can be reversed, that is, the address data 9 can be recorded between the identification mark bit 11 and the parity data 8. The parity data 8 and the address data 9 are recorded from their respective LSBs (least significant bits).

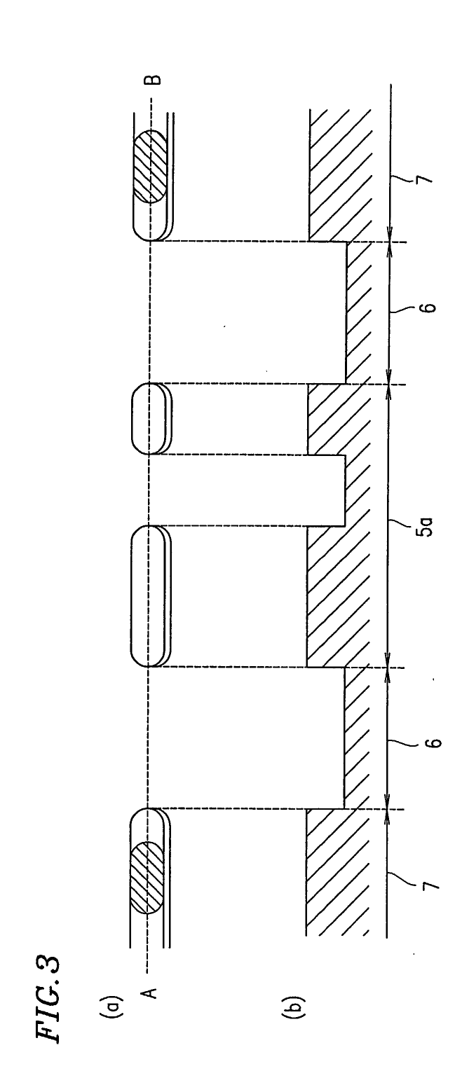

FIGS. 3(a) and 3(b) are magnified views each illustrating portions in which the address information 5 of the lead of the sector shown in FIG. 2(b) is recorded. In this example, a code alphabet 0 (5a) is represented as the address information 5. FIG. 3(a) is a three-dimensional view illustrating portions in which the address information is recorded. FIG. 3(b) is a cross-sectional view taken along line A-B of FIG. 3(a). The recorded data 7 is recorded by irradiating convex portions on a disk with a focused laser beam so as to form portions having different reflection coefficients. The address information 5a (code alphabet 0) is recorded by forming a pattern of concaves and convexes surrounded by concave portions (the gaps 6) in the disk.

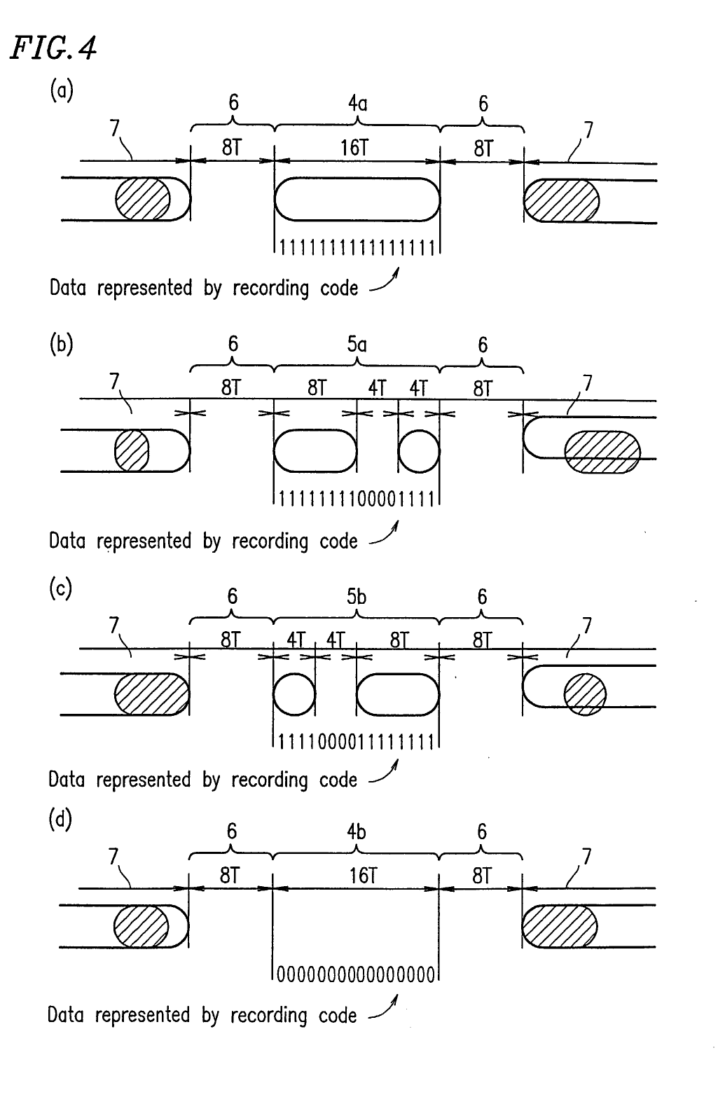

FIGS. 4(a)-4(d) illustrate various types of code alphabets of address information. FIG. 4(a) illustrates an example (4a) of the identification mark 4 of the code alphabet included in the address information. The identification mark 4a is recorded by embossing and the recorded data 7 is recorded by partially changing a reflection coefficient of a recording film. Data to be recorded is recorded using, for example, a recording code such as a run-length-limited recording code, e.g., a 8/16 recording code. The identification mark 4a is represented by a 16T mark (T denotes a channel clock cycle of a recording code of sector data). Accordingly, data is represented by 1111111111111111 in a recording code. The gap 6 having a length of 8T is provided between recorded data and the identification mark 4a so as to prevent the recorded data from being overwritten by address information bits or an identification mark.

FIG. 4(b) shows a code alphabet 0 included in address information. The code alphabet 0 (5a) is recorded by embossing and the recorded data 7 is recorded by partially changing a reflection coefficient of a recording film. The code alphabet 0 (5a) is represented by an 8T mark, a 4T space and a 4T mark. Accordingly, data is represented by 1111111100001111 in a recording code. The gap 6 having a length of 8T is provided between the recorded data and the identification mark so as to prevent the recorded data from being overwritten by address information bits and the identification mark.

FIG. 4(c) shows a code alphabet 1 (denoted by reference numeral 5b) included in the address information. The code alphabet 1 (5b) is recorded by embossing and the recorded data 7 is recorded by partially changing a reflection coefficient of a recording film. The code alphabet 1 (5b) is represented by a 4T mark, a 4T space and an 8T mark. Accordingly, data is represented by 1111000011111111 in a recording code. The gap 6 having a length of 8T is provided between the recorded data and the identification mark so as to prevent the recorded data from being overwritten by address information and the identification mark.

FIG. 4(d) shows another example of the identification mark of the code alphabet included in the address information. The identification mark 4b is in a state where no emboss-pits are formed. The recorded data 7 is recorded by partially changing a reflection coefficient of a recording film. Data to be recorded is recorded using, for example, a recording code such as a run-length-limited recording code, e.g., a 8/16 recording code. The identification mark 4b is represented by a 16T space (T denotes a channel clock cycle of a recording code of sector data). Accordingly, data is represented by 0000000000000000 in a recording code. The gap 6 having a length of 8T is provided between the recorded data and the identification mark so as to prevent the recorded data from being overwritten by the address information or the identification mark.

In such code alphabets, a correlation between alphabets is low, and therefore identification of each code alphabet is easy. Further, reproduced data is obtained by detecting a peak in a reproduced signal, and thus is hardly affected by noise or distortion of a reproduction waveform. When a long mark is present in a first part of the address information part, the mark can be detected as being “0”. When a long mark is present in a last part of the address information part, the mark can be detected as being “1”. Therefore, as compared to a conventional example, the reliability of address reproduction is significantly improved.

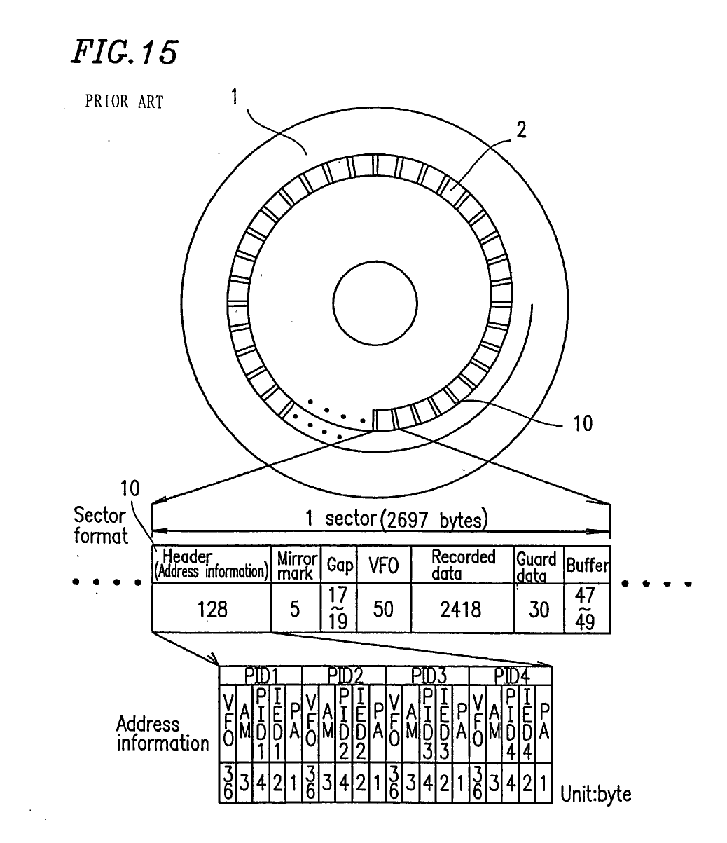

In the conventional example of FIG. 15, the data quantity of address information required in a single sector is 128 bytes. However, in the present embodiment, the data quantity of address information required in a single sector is 32T which corresponds to 2 bytes when converted into the data quantity of the 8/16 recording code, and therefore redundancy of the address information is significantly reduced. According to the disk medium of the present invention, by dispersedly recording address information in a sector group, it is possible to reduce the redundancy of address information while the reliability of the address information reproduction can be significantly improved.

In the above description, although the number of sectors included in a single sector group is 32, the present invention is not limited to this. The number of sectors can be suitably changed according to the quantity of information to be recorded. When the number of sectors included in a single sector group is changed, the number of bits in address information is correspondingly changed.

### EXAMPLE 2

An error correcting scheme for the disk medium 200 of Embodiment 1 is described below as Example 2.

In a disk medium in which address information is dispersedly recorded, it may happen that the address information is not correctly reproduced due to a flaw or a stain on the disk medium. When there is an address information bit which cannot be reproduced, a sector group corresponding to such an address becomes unavailable. In order to prevent this, as described with respect to Example 1, the address information data in the disk medium according to the present invention is configured so as to include address data to which parity data is added. Therefore, even when there is a bit which cannot be reproduced, by performing an error correction on the address data, it is possible to perform address reproduction.

An error correction ability required for address information of the disk medium 200 is described below. Typical errors caused to information recorded in a disk medium include a burst error and a random error. Regarding the burst error, when a section on a disk medium includes a significant number of errors as compared to the number of errors in other sections, an error in this section is referred to as a burst error. There are two types of 3-bit burst errors described below in a section surrounded by erroneous bits in which a large number of errors are present. One is a 3-bit continuous error and the other is an error in which bits at both ends in three consecutive bits are erroneous. On the other hand, the random error refers to errors each of which is individually caused in units of one bit.

When a physically required burst error correction length is 6 mm, the recording density is 0.138 μm/bit, and a used sector format corresponds to a sector format which is obtained by representing the data quantity in the header of the format shown in FIG. 15 so as to be changed from 128 bytes to 2 bytes, the data quantity corresponding to the burst error correction length of 6 mm amounts to 5435 bytes which is equivalent to data in about 2.1 sectors. In order to realize such a burst error correction, address information is also required to have an equivalent or higher correction ability. Therefore, as the correction ability of the address information, a 3-bit burst error correction corresponding to address information for three sectors is required. Further, since an address reproduction error is considered to occur due to a flaw on a disk medium, at least 2-bit random error correction ability is required on the assumption that there is a linear flaw corresponding to a length of a maximum diameter on the disk. Therefore, the error correction ability required for address information is the 3-bit burst error correction ability or the 2-bit random error correction ability.

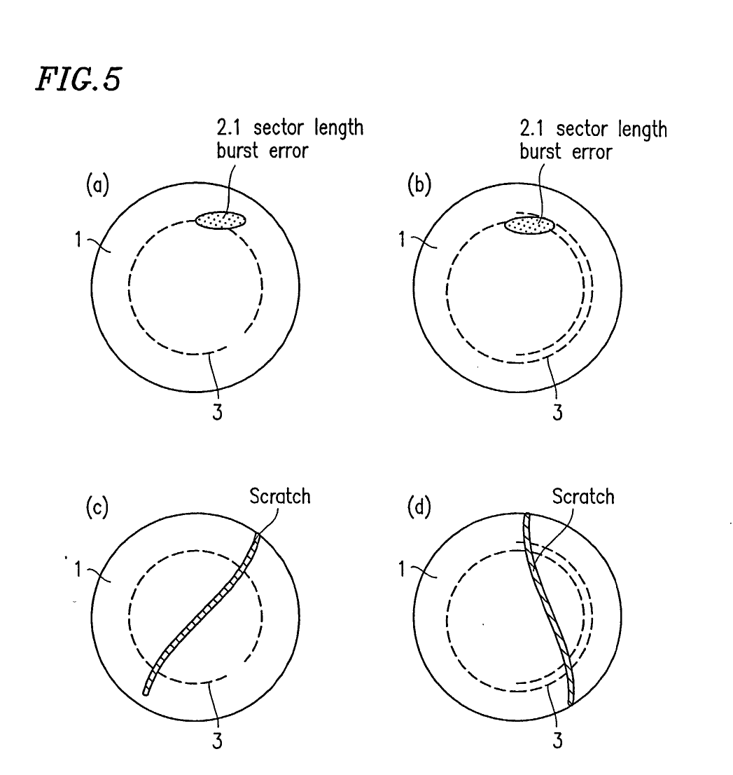

The required error correction ability varies according to a length of the sector group. FIGS. 5(a) -(d) are views each showing the number of reproduction errors in address information when there is a flaw or a stain on the disk medium 200. FIG. 5(a) shows a case where a burst error of a 2.1 sector length is caused to a disk medium in which each sector group 3 has a length which is less than a track length (in the case of the disk medium 200). FIG. 5(b) shows a case where a burst error of 2.1 sector length as in the case of FIG. 5(a) is caused to a disk medium in which each sector group has a length which is equivalent to or more than one track length. FIG. 5(c) shows a case where a linear flaw is caused to a disk medium in which each sector group 3 has a length which is less than one track length (in the case of the disk medium 200). FIG. 5(d) shows a case where a linear flaw same as that in the case of FIG. 5(c) is caused to a disk medium in which each sector group has a length which is equivalent to or more than one track length.

In the case of FIG. 5(a), there is a possibility that address information of up to three consecutive bits is lost in a single sector group, while in the case of FIG. 5(b), there is a possibility that address information of up to three consecutive bits is lost at two locations in a single sector group. This is because a single sector group extends over two tracks. In the case of FIG. 5(a), there is a possibility that address information of up to any two bits is lost in a single sector. In the case of FIG. 5(d), there is a possibility that address information of up to any four bits is lost in a single sector. In this manner, when the physical length of a signal sector group is equivalent to or more than one track, the quantity of address information which is caused to be lost due to a flaw, a stain, etc., is doubled as compared to the case where the physical length of a single sector group is less than one track length.

Next, specific methods for realizing the 3-bit burst error correction ability and 2-bit random error correction ability which are error correction abilities required for address information are described.

In the disk medium 200, the address data is formed of 19 bits and the parity bits are 12 bits in total. The 3-bit burst error correction or the 2-bit random error correction must be performed using 12-bit parity data. When these conditions are applied to a BCH (Bose-Chaudhuri-Hocquenghem) code which is a conventional code, a BCH code is considered as having a code length of 31 bits, the number of address data bits which is 21, and a coefficient of a generating polynomial expression which is 769h. However, this code has a 2-bit correction ability, and therefore conditions for the required correction ability are not satisfied.

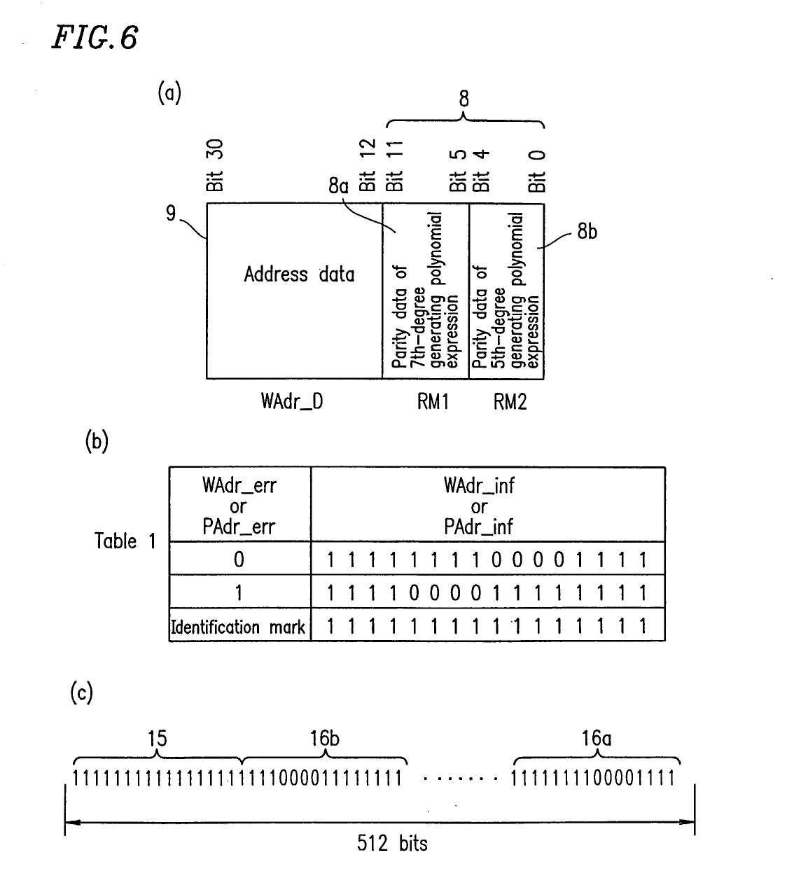

In the present embodiment, in order to obtain the above-described error correction ability, a combination of two shortened cyclic codes is used as the parity data. That is, as shown in FIG. 6(a), two types of parities are calculated from address data using two types of generating polynomial expressions and are added to the address data. In the present embodiment, C9h (h: hexadecimal number) is used as a coefficient of a seventh-degree generating polynomial expression and 2Fh is used as a coefficient of a fifth-degree generating polynomial expression. A burst error correction bit number of a code encoded using this seventh-degree polynomial expression is three and a burst error correction bit number of a code encoded using this fifth-degree polynomial expression is one. A minimum distance between the error correction codes of the present invention including a combination of these two codes is 5, and therefore the 2-bit random error correction is possible. Further, a combination of syndromes generated from two parities and representing positions and states of errors is unique to each of 1-bit errors, 2-bit errors, and 3-bit burst errors in an entire code, and therefore all of these errors can be corrected by two syndromes.

As an example of a similar generating polynomial expression, there is a fifth-degree generating polynomial expression having a coefficient of 01h, 02h, or the like, when the coefficient of the seventh-degree generating polynomial expression is C9h. It should be noted that in the example of FIG. 6(a), a code length of the correction code (20-bit address data, 12-bit parity data) is calculated on condition that a most significant bit (MSB) of address data is 0 and the address data is formed of 19 bits.

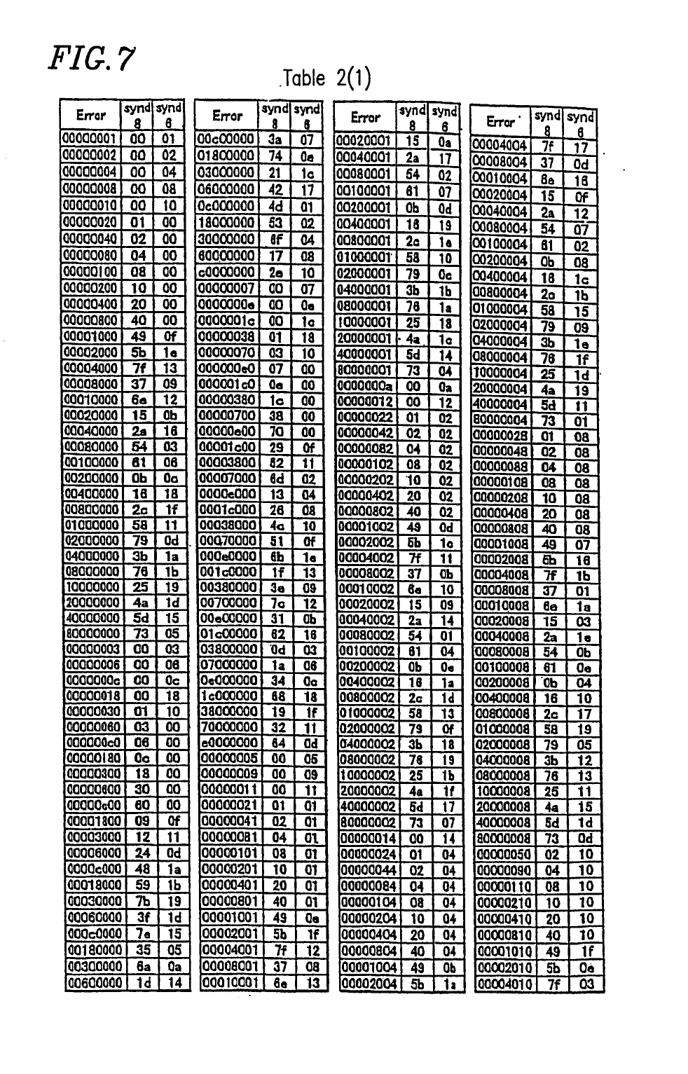

FIGS. 7, 8 and 9 show syndromes with respect to an error pattern of address information data, i.e., the error correction code (coefficients of generating polynomial expressions are 2Fh and C9h) of the present embodiment. In the section denoted by “Error”, a position of an error in the 32-bit address information data is indicated by “1”. For example, 00000001 in the “Error” section represents that the LSB has an error. The “synd6” and “synd8” sections respectively indicate 5-bit syndromes obtained from a 6-bit generating polynomial expression and 7-bit syndromes obtained from an 8-bit generating polynomial expression. The “Error” section includes all of the 1-bit errors, 2-bit errors and 3-bit burst errors. From this table, it is appreciated that all of combinations of synd6 and synd8 are different.

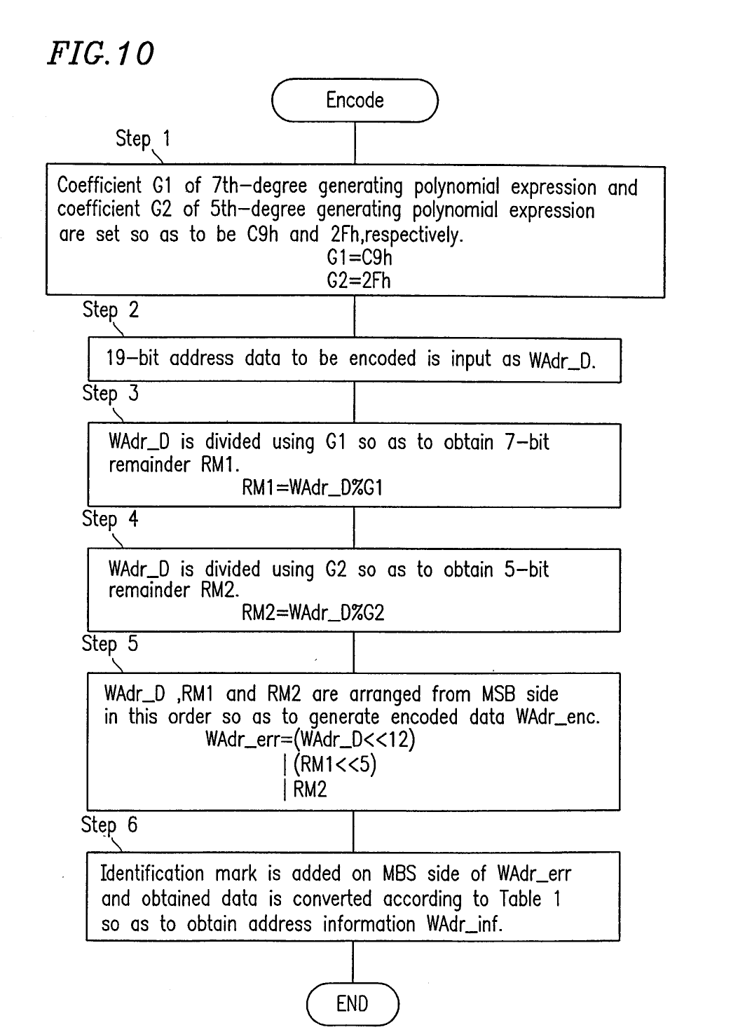

FIG. 10 shows an example of a method for encoding 19-bit address data, i.e., a method for generating address information. Process of this method is divided into six steps. Step-by-step description of the process is provided below.

Step 1

A coefficient G1 of a seventh-degree generating polynomial expression and a coefficient G2 of a fifth-degree generating polynomial expression are set so as to be C9h and 2Fh, respectively.

Step 2

19-bit address data to be encoded is input as WAdr_D.

Step 3

The 19-bit address data WAdr_D is divided using the seventh-degree generating polynomial expression G1 so as to obtain a 7-bit remainder RM1. This becomes parity data of the seventh-degree generating polynomial expression. It should be noted that “%” shown in FIG. 10 denotes a remainder operation.

Step 4

The 19-bit address data WAdr_D is divided using the fifth-degree generating polynomial expression G2 so as to obtain a 5-bit remainder RM2. This becomes parity data of the fifth-degree generating polynomial expression.

Step 5

Parity data RM1 and RM2 are added to a lower-order side of the address data WAdr_D in this order so as to obtain encoded address data WAdr_err, which amounts to data of 3.1 bits including 19-bit address data, 7-bit parity data of the seventh-degree generating polynomial expression and 5-bit parity data of the fifth-degree generating polynomial expression.

A format of encoded address data obtained in the above-described process is as shown in FIG. 6(a). The 12-bit parity data 8 is added to the lower-order side of the 19-bit address data 9. The parity data 8 is grouped into, from an upper order, parity data 8a of the seventh-degree generating polynomial expression generated using the remainder operation of the seventh-degree generating polynomial expression, and parity data 8b of the fifth-degree generating polynomial expression generated using the remainder operation of the fifth-degree generating polynomial expression.

Further, a minimum intercode distance with respect to this 31-bit code is determined so as to be 5, and therefore it is possible to obtain a 2-bit random error correction ability. It should be noted that “<<” shown in FIG. 10 indicates a shift operation.

Step 6

An identification mark is added at the MSB (Most significant bit) side of the encoded address data WAdr_err and obtained data is converted according to Table 1 of FIG. 6(b) so as to obtain address information data WAdr_inf.

FIG. 6(c) is an example of conversion from the encoded address data to address information data. A 16-bit leader indicates a data series 15 of a recorded and encoded identification mark, which is a data series obtained by recording and encoding the identification mark. The data series is represented by “1111111111111111”. The next 16-bit data indicates a recorded and encoded data series 16b of “1”. The data series is represented by “1111000011111111”. The last 16-bit data is a data series “1111111100001111” which corresponds to a recorded and encoded data series 16a of “0”. A set of address information is converted into 512-bit data when recoded.

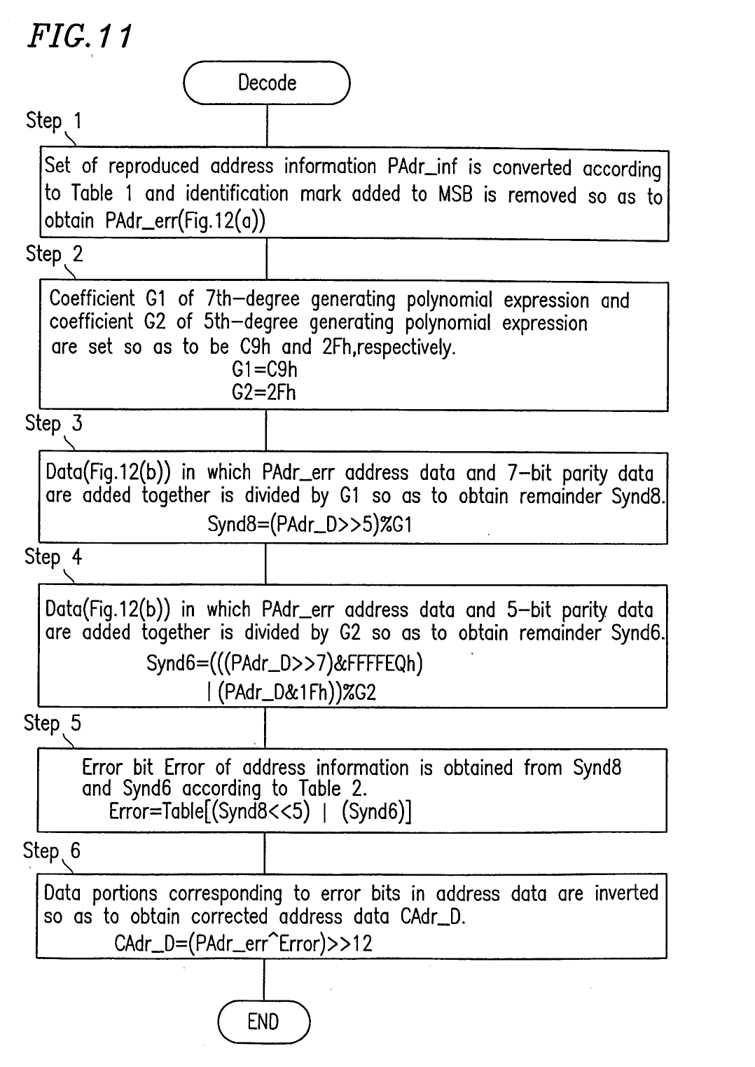

FIG. 11 shows an example of a method for decoding address information data. The process of this method is divided into six steps. Step-by-step description of the process is described below.

Step 1

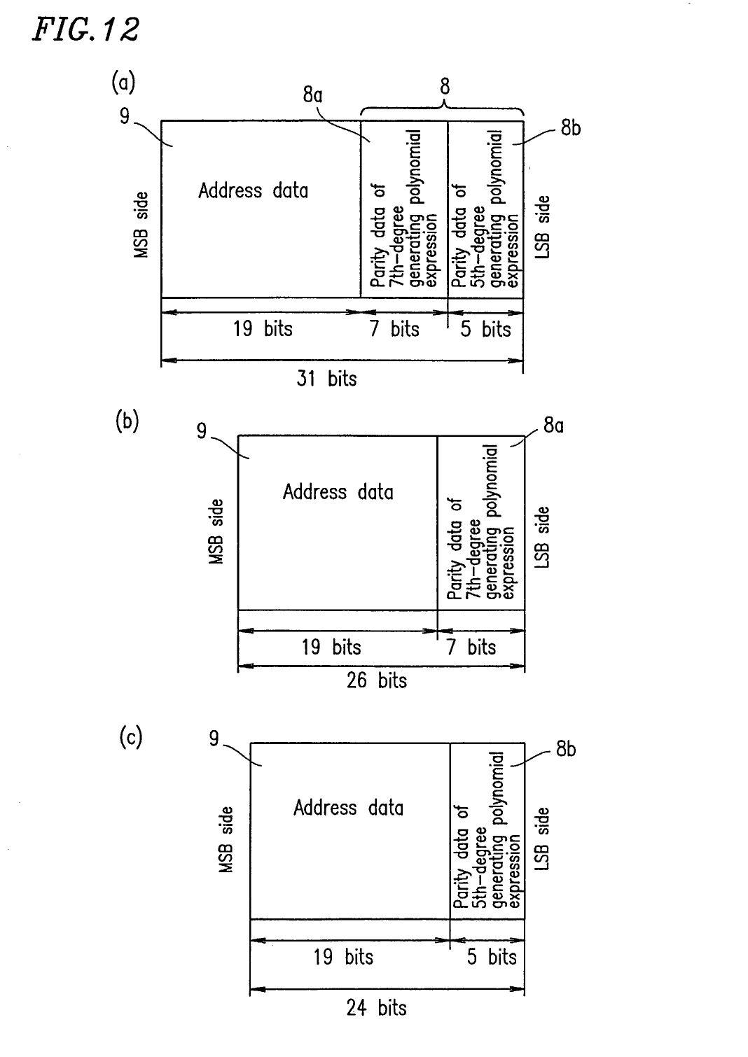

A set of reproduced address information PAdr_inf is converted according to Table 1 and an identification mark added to the MSB of obtained data is removed from the obtained data so as to obtain PAdr_err. FIG. 12(a) shows a data format of the PAdr_err.

Step 2

The coefficient G1 of the seventh-degree generating polynomial expression and the coefficient of the fifth-degree generating polynomial expression are set so as to be C9h and 2Fh, respectively.

Step 3

26-bit data in which 19-bit address data 9 and parity data 8a of the seventh-degree generating polynomial expression are added together is divided by the coefficient G1 of the seventh-degree generating polynomial expression so as to obtain a 7-bit remainder. This remainder is used as syndrome Synd8 of the seventh-degree generating polynomial expression. FIG. 12(b) shows a data format of the 26-bit data in which 19-bit address data 9 and parity data 8a of the seventh-degree generating polynomial expression are added together.

Step 4

24-bit data in which 19-bit address data 9 and parity data 8b of the fifth-degree generating polynomial expression are added together is divided by the coefficient G2 of the fifth-degree generating polynomial expression so as to obtain a 5-bit remainder. This remainder is used as syndrome Synd6 of the fifth-degree generating polynomial expression. FIG. 12(c) shows a data format of the 24-bit data in which the 19-bit address data 9 and the parity data 8b of the fifth-degree generating polynomial expression are added together.

Step 5

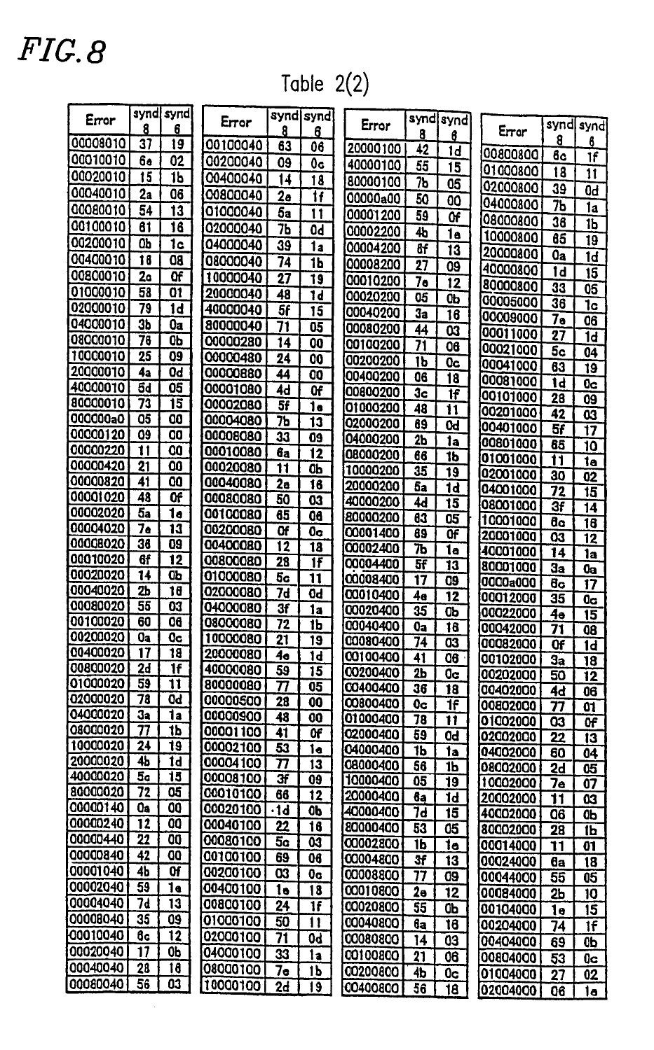

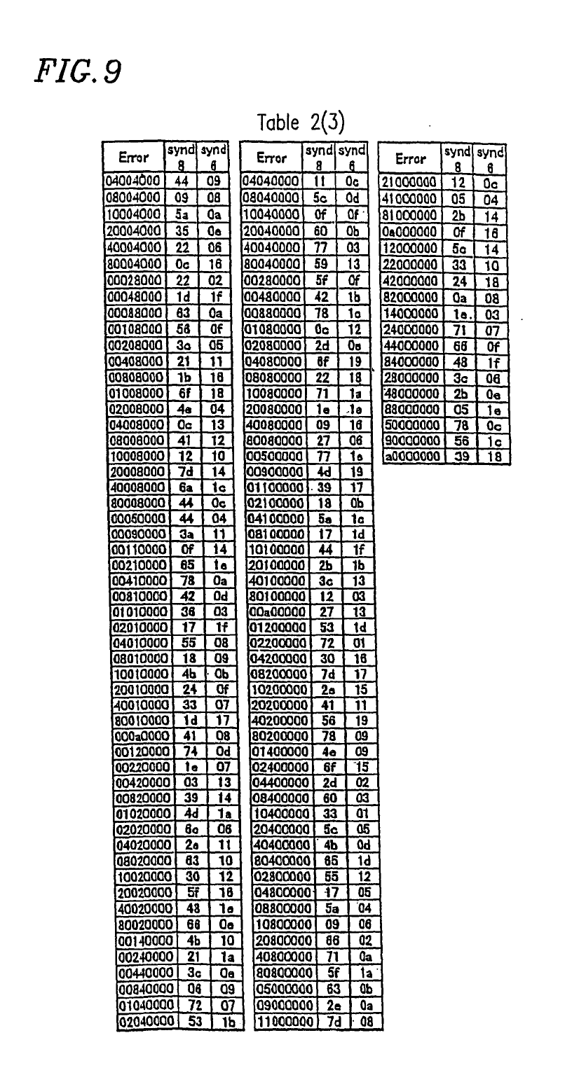

12-bit data in which the Synd 6 and the Synd 8 are added together is input so as to obtain an error pattern Error corresponding to these two syndromes according to Table 2 with respect to 32-bit error pattern outputs. Table 2 is continuously shown from FIG. 7 (Table 2(1)) through FIG. 8 (Table 2(2)) to FIG. 9 (Table 2(3)).

Step 6

An exclusive logic sum of PAdr_D and Error is calculated so as to obtain corrected address data CAdr_D.

Next, specific examples of encoding and decoding of the address information described in the above example are described. When the address data is 13EC0h, a remainder obtained by dividing 13EC0h using a generating polynomial expression 2Fh having a 6-bit coefficient is 16h. Further, a remainder obtained by dividing 13EC0h using a generating polynomial expression C9h having an 8-bit coefficient is 4Bh. The address data 13EC0h, the 7-bit remainder 4Bh and the 5-bit remainder 16h are arranged from an upper-order bit in this order so as to obtain 31-bit encoded data 13EC0976h.

Considering that errors are caused to the 19-bit and 9-bit data portions in the encoded data when reproduced, the 19-bit and 9-bit data portions are inverted, i.e., address information reproduction data becomes 13E40B76h.

Upper-order 19 bits in the obtained address information reproduction data is again divided using the generating polynomial expression 2Fh having a 6-bit coefficient, so that a remainder 03h is obtained. Similarly, the upper-order 19 bits in the obtained address information reproduction data is again divided using the generating polynomial expression C9h having an 8-bit coefficient, so that a remainder 44h is obtained. According to FIGS. 7, 8 and 9, errors corresponding to these two syndromes are found to be 00080200, so that it is found that the 19-bit and 9-bit data portions have errors. The 19-bit and 9-bit data portions in the address information reproduction data are inverted so as to obtain corrected address information data 13EC0976h, which is the same as the encoded data and therefore it is found that the errors are corrected.

Further, when a binary circuit cannot determine whether the reproduction data of address information is either “0” or “1” or when a servo circuit detects that tracking or focusing for reproducing address information is deviated by a value equal to or more than a prescribed value, the binary circuit or servo circuit outputs the status (referred to as “pointer information”) to an address information decoding means, so that the address information decoding means generates two types of address information reproduction data for both cases where “0” is set as the address information bit and “1” is set as the address information bit and performs a decode operation on the two types of address information reproduction data. When errors in both or either of two types of created address information reproduction data are corrected, one type or two types of corrected address data is/a reconsidered as being correct address data. This allows a burst error correction of up to four bits or a random error correction of three bits to be performed.

As described above, according to the present embodiment, by combining two types of parities as parity data of address information, it is possible to correct a 3-bit burst error or a 2-bit random error. Further, when pointer information is available, it is possible to correct a 4-bit burst error or a 3-bit random error. Therefore, in the case where address information is dispersedly recorded in a sector group, even when a burst error or random error is caused due to a stain, a flaw, or the like, it is possible to perform error correction, thereby increasing the reliability of the address information reproduction.

Furthermore, by using two types of identification marks shown in FIGS. 4(a) and 4(d), it is possible to further increase the number of bits in the address information by one bit, and therefore the present invention is applicable to address data of 20 bits in total, i.e., a disk having a recording capacity of 236 bytes. For example, when the identification mark shown in FIG. 4(d) is used, the LSB of the address data bit is set so as to be “0”, and when the identification mark shown in FIG. 4(a) is used, the LSB of the address data bit is set so as to be “1”. Therefore, it is possible to use address information following the identification mark so as to represent other data, i.e., 19-bit address data and 12-bit parity data, thereby representing an address of 20 bits in total.

Similar to the address information of 19 bits, error correction of a 20-bit address can be performed since a combination of syndromes is unique. Further, similar to the 19-bit address data, a combination of two syndromes used for 20-bit address data is unique. This is apparent from a fact that a code length of the correction code of the present invention originally includes 32 bits, i.e., 20-bit address data and 12-bit parity data, and the most significant bit (MSB) is 0 in the case of the 19-bit address data. Therefore, in the case of the 20-bit address data, it is also possible to correct all of one bit errors, two bit errors and three bit burst errors using two syndromes.

In this example, two types of sector groups each having different identification marks in their respective leads are alternately arranged, and therefore when a sector group being reproduced is deviated from a sector group to be reproduced by an odd number of addresses, it is possible to detect such deviations by simply reproducing the identification marks.

It should be noted that it is also possible to perform similar burst error correction and random error correction by interleaving random error correction codes. In this case, each address information length is lengthened, thereby increasing the number of sectors included in a sector group.

(Embodiment 3)

Specific examples of methods for recording and reproducing a disk using the error correcting scheme according to Embodiment 2 are described as Embodiment 3.

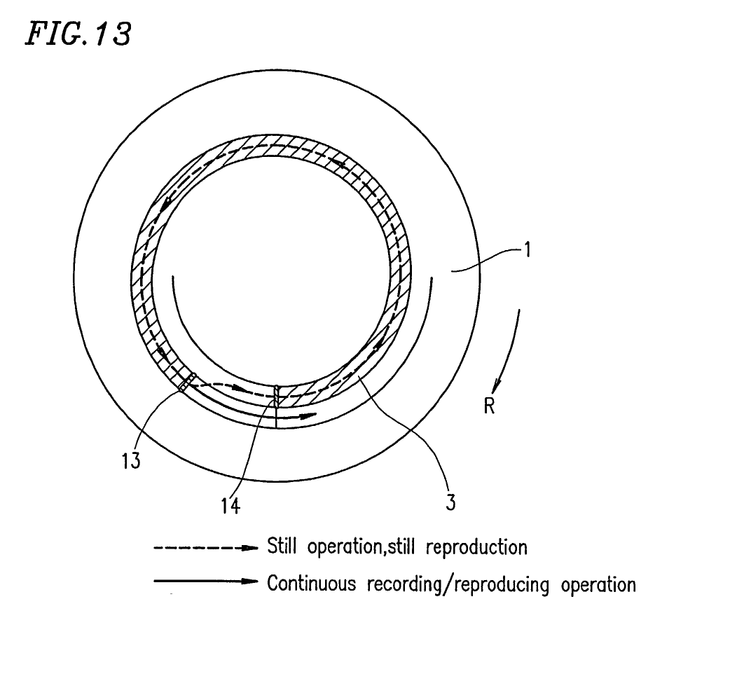

Referring to FIG. 13, basic recording and reproducing operations (hereinafter, “recording and reproducing” is abbreviated to “recording/reproducing”) on the disk medium 200 according to Example 1 are described.

The recording/reproducing operation includes a seek operation for moving an optical head to an address represented by a record/reproduce command from a host computer, a still operation for holding the optical head at a record/reproduce start position, and an operation for actually performing a recording/reproducing operation using the optical head.

Usually, upon receipt of the record/reproduce command from the host computer, a disk drive controls the optical head so as to move to a position designated by the record/reproduce start address represented by the record/reproduce command. This operation is referred to as the “seek operation”.

In general, when the seek operation is completed, reading an address of a record sector from which a recording/reproducing operation is started is performed as a preparation stage before starting the recording/reproducing operation. Then, a track jump operation is repeatedly performed along a direction opposite to track running direction R such that the optical head remains at a track including a record/reproduce start sector. This operation is referred to as the “still operation”.

In the case of the disk medium of the present invention, in order to confirm a position of a sector group from which a recording/reproducing operation is started before starting the recording/reproducing operation, an address of one sector group before a record/reproduce start sector group is read, that is, a still operation is required to be performed at the address of one sector group before the record/reproduce start sector group. The reason for this is that in the present invention, a timing of recognizing the record/reproduce start address is substantially after the passage of the optical head through the sector group corresponding to the record/reproduce start address, and therefore if one address before a target address (one sector group before a target sector group) is not recognized, it is not possible to start a recording/reproducing operation from a sector group represented by the record/reproduce start address. Similarly, an address targeted for a seek operation on the disk medium of the present invention corresponds to one sector group before the sector group represented by the record/reproduce start address.

The recording/reproducing operation is performed for each unit of ECC block. In the disk medium of the present embodiment, a sector group corresponds to an ECC block. That is, the lead of the record/reproduce start sector group corresponds to the leader of the ECC block, and therefore it is possible to perform the recording/reproducing operation with respect to the lead of the ECC block from a prescribed sector by starting the record/reproduction operation after the identification mark is detected. Therefore, the still operation performed on the disk medium of the present embodiment is for the purpose of reading address information of one sector group before the record/reproduce start sector group and an identification mark of the record/reproduce start sector group and perform a track jump over one track along a direction opposite to a track running direction so as to continuously read the address information of one sector group before the record/reproduce start sector group again and again.

In FIG. 13, an arrow with a dotted line indicates a relative movement of the head with respect to the disk medium during the still operation. Address information bits for thirty-one sectors are reproduced from the identification mark 14 of one sector group before the record/reproduce start sector group so as to recognize the record/reproduce start address, and further an identification mark 13 of the record/reproduce start sector is reproduced and recognized. Then, by performing a track jump over one track along a direction opposite to the track running direction towards the internal circumference of the disk, the identification mark 14 of the one sector group before the record/reproduce start sector group is reproduced again. The still operation is performed by repeatedly performing a series of these operations. Since the disk medium of the present embodiment includes sector groups each having a length shorter than one track length, as indicated by the arrow with a dotted line, the still operation is completed in one rotation of the disk. Similarly, the still operation is completed in one rotation of the disk with respect to a still-reproduce operation in which reproduction of a single sector group is repeatedly performed, or a verify-reproduce operation for verify-recording a single sector group.

The arrow with a dotted line shown in FIG. 13 indicates the movement of the head at the time of starting the recording/reproducing operation. When shifting from the still operation to the recording/reproducing operation, the shift to the recording/reproducing operation is performed after reading the identification mark 13 of the record/reproduce start sector group.

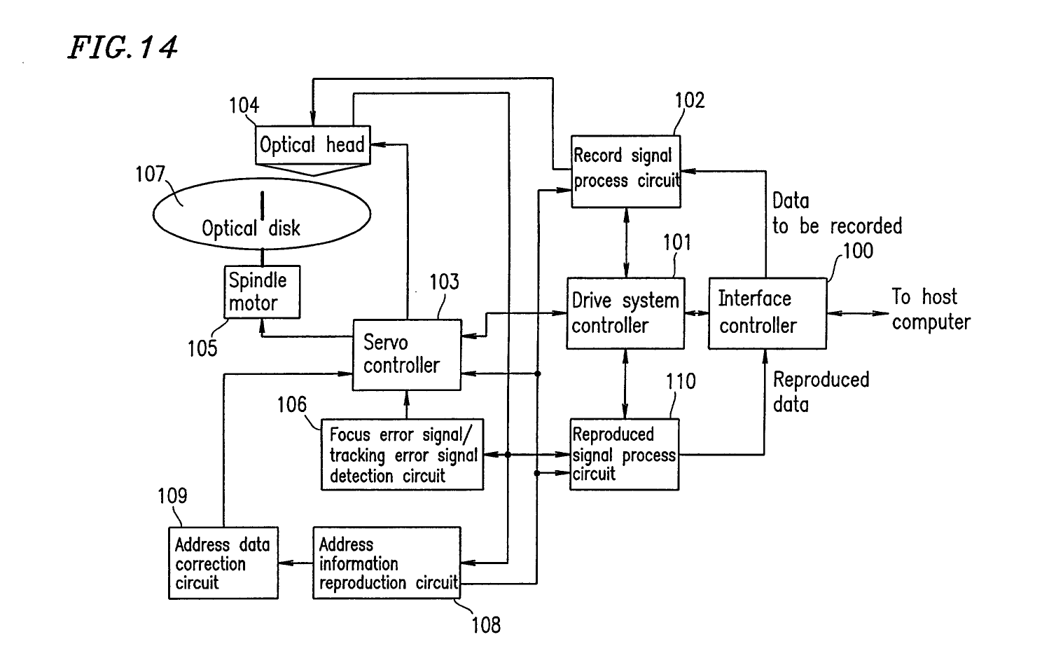

A disk drive for realizing the recording/reproducing operation as described above is described with respect to a series of recording/reproducing operations thereof. FIG. 14 shows an example of a structure of such a disc drive.

An operation for recording is now described. The recording operation is performed according to a command from a host computer, i.e., a record command, such that data to be recorded, which is transmitted by the host computer and has a size represented by the record command, is recorded at an address of a disk which is represented by the record command.

When the record command is transmitted by the host computer to a drive system controller 101 via an interface controller 100, the drive system controller 101 outputs a command for a serve controller 103 to cause an optical head 104 to seek an address −1 represented by the record command as a target address.

The servo controller 103 controls the optical head 104 to move to the address −1 represented by the record command. In this case, the servo controller 103 controls a spindle motor 105 so as to rotate at a prescribed rotation speed. The servo controller 103 also controls the optical head 104 according to a focus error signal from a focus error signal/tracking error signal detection circuit 106 so as to focus a laser beam on an optical disk 107.

When the optical head 104 comes close to the target address, the servo controller 103 controls the optical head 104 according to a tracking error signal from the focus error signal/tracking error signal detection circuit 106 so as to stop the movement of the optical head 104 and focus a laser beam on a track of the optical disk 107. In this state, the optical disk 107 is brought into a state where address information can be reproduced therefrom. A reproduced signal from the optical head 104 is input to an address information reproduction circuit 108 and the address information reproduction circuit 108 outputs binarized address information which is input to an address data correction circuit 109. The address data correction circuit 109 outputs corrected address data to the servo controller.

The error correction signal described in the above-described embodiment is used as this address information such that the address data correction circuit 109 performs a decode operation on an error correction code, that is, an error correction process is performed.

The servo controller 103 senses a position of the optical head 104 based on this address data, recognizes a distance from the optical head 104 to a target address, and controls the optical head 104 so as to move toward a direction of the target address again. This movement of the optical head 104 and address reproduction operation are repeated so that the optical head 104 moves to the location of the target address.

When the optical head 104 has moved to the position represented by the target address, the servo controller 103 notifies the drive system controller 101 of completion of the movement. Further, the servo controller 103 performs a still operation at the target address.

The drive system controller 101 issues a command for the interface controller 100 to output data to be recorded from the host computer to the record signal process circuit 102 simultaneously with issuing a command for the record signal process circuit 102 to start a recording operation by reproducing the next identification mark. Further, the drive system controller 101 issues a command for the servo controller to cease the still operation when a first identification mark after the next identification mark is read and move the optical head along the track.

When the record signal process circuit 102 receives a signal representing that the identification mark is detected from the address information reproduction circuit 108, the record signal process circuit 102 performs a prescribed process on the data to be recorded and outputs the processed data to the optical head 104, so that the optical head 104 records the processed data to be recorded on the optical disk 107.

Next, a series of reproducing operations performed by the disk drive for reproducing data recorded on the disk medium 200 is described.

The reproducing operation is performed, according to a reproduce command from the host computer, so as to reproduce data having a size represented by the reproduce command from an address of the optical disk 107 also represented by the reproduce command and transmits the reproduced data to the host computer.

When the reproduce command is transmitted by the host computer to the drive system controller 101 via the interface controller 100, the drive system controller 101 issues a command for the servo controller 103 to cause the optical head 104 to seek a target address (an address −1 represented by the reproduce command).

The servo controller 103 controls the optical head 104 so as to move to the target address. At this time, the servo controller 103 controls the spindle motor 105 so as to rotate at a prescribed speed. Further, the servo controller 103 controls the optical head 104, according to a focus error signal from the focus error signal/tracking error signal detection circuit 106, so as to focus a laser beam on the optical disk 107.

When the optical head 104 comes close to the target address, the servo controller 103 controls the optical head 104 according to a tracking error signal from the focus error signal/tracking error signal detection circuit 106 so as to stop the movement of the optical head 104 and focus a laser beam on a track of the disk. In this state, the disk is brought into a state where address information can be reproduced therefrom. A reproduced signal from the optical head 104 is input to an address information reproduction circuit 108 and the address information reproduction circuit 108 outputs binarized address information which is input to the address data correction circuit 109. The address data correction circuit 109 outputs corrected address data to the servo controller 103. The servo controller 103 senses a position of the optical head 104 based on this address data, recognizes a distance from the optical head 104 to a target address, and controls the optical head 104 so as to move again. This movement of the optical head 104 and address reproduction operation are repeated so that the optical head 104 moves to the target address.

In the reproducing operation described above, when it is detected that a size of an envelope of the reproduced signal representing bits in the reproduced address information are not in a prescribed range or it is detected, based on the reproduced signal representing the bits in the address information, that relative positions of the optical head and the track are not in a prescribed range, reproduced data bits corresponding to the bits in the reproduced address information can be used as erasure bits so as to perform an erasure correction.

After the movement of the optical head 104 to the target address is completed, the servo controller 103 notifies the drive system controller 101 of the completion of the movement. Further, the servo controller 103 performs a still operation at the target address.

The drive system controller 101 issues a command for the interface controller 100 to output reproduced data from the reproduced signal process circuit to the host computer simultaneously with issuing a command for the reproduced signal process circuit 110 to start a reproducing operation from the next identification mark. Further, the drive system controller 101 issues a command for the servo controller to cease the still operation when a first identification mark after the next identification mark is read and move the optical head along the track.

When the reproduced signal process circuit 110 receives a signal representing that the identification mark is detected from the address information reproduction circuit 106, the reproduced signal process circuit 110 performs a prescribed process on the reproduced signal from the optical head 104 and outputs reproduced data to the host computer via the interface controller 100.

As described above, according to the recording/reproducing method of the present embodiment, in a disk medium in which address information is dispersedly recorded in a sector group, a period of time required for rotation for shifting the still operation to the recording/reproducing operation is shortened, specifically, overhead in a recording/reproducing operation is suppressed so as to be within one rotation of the disk, thereby providing a disk medium in which a period of time required for a record/reproduce access is short. Similarly, a still-reproduce operation for a single sector group or a verify-reproduce operation for verify-recording is completed in one rotation of the disk.

In the case of using the disk drive of this embodiment so as to perform a recording/reproducing operation on the disk medium 200, a highly reliable recording/reproducing operation can be performed by confirming the quality of obtained address information. Specifically, the extent of errors included in the address information can be detected. When a highly reliable recording/reproducing operation is required according to the extent of errors, it is possible to perform a more reliable recording/reproducing operation by determining whether or not a recording/reproducing operation should be performed on a sector group corresponding to a reproduced address using the presence of errors, the number of errors, etc., as criteria for the determination. On the contrary, by setting the criteria for determination so as not to be strict, it is possible to perform a recording/reproducing operation when an unnecessarily-high reliability is not required.

Further, when the track targeted for a recording/reproducing operation is deviated due to disturbance or the like, it is often happens that there is one-track deviation. When the recording/reproducing operation is sequentially performed, address data is incremented. That is, the LSB of the address data continually varies. Therefore, by configuring address information such that the LSB of address data is provided immediately after the identification mark, even when the track targeted for a recording/reproducing operation is deviated, it is possible to detect, based on a comparison with expected address information, that the recording/reproducing operation is performed on a sector group which is deviated from a target sector group by one sector group simply by reproducing the identification mark and the LSB of the address data. As a matter of course, such detection can be performed in a similar manner with respect to a case where the sector group is deviated by an odd number of sector groups.

However, there could be a case where track deviation is mistakenly detected due to erroneous reproduction of the LSB of the address data. In order to cope with this, the address information is configured such that the identification mark, parity data and the LSB of the address data are arranged in this order, thereby realizing higher reliability of detection. Since the random error correction ability of the error correction signal according to the present invention is a 2-bit correction ability, for example, when a piece of address information is different in the number of bits in address data from another piece of address by one bit, they are different in the number of bits in parity data from each other by four bits or more. Therefore, when expected address information is compared to reproduced address information and parity data of the expected address information is different in the number of bits from the LSB of the reproduced address data by bits equal to or more than a prescribed number, for example, four bits or more, it is possible to determine that the sector including the address information being reproduced is not present in expected sector group. Therefore, in the case of sequentially performing recording/reproducing operations, or the like, it is possible to cease the recording/reproducing operation without reproducing entire 32-bit address information, thereby increasing the reliability of the recording/reproducing operation.

### INDUSTRIAL APPLICABILITY

According to the present invention, in a disk medium, a plurality of positionally continuous sectors form a sector group, a prescribed unit of address information including at least 0, 1 and an identification mark is dispersedly recorded in the plurality of sectors in the sector group. As an error correction code included in the address information, address data to which parity data is added is used. Further, a combination of two codes is used as the parity data and is used for error correction in an address reproduction operation.

With this structure, redundancy in address is reduced, thereby significantly improving the reliability of address information reproduction and an error correction ability of the address information. According to the present invention, it is possible to provide a disk medium having high reliability of address reproduction, a disk recording method which is highly reliable with respect to address reproduction in a recording operation, and a disk reproducing method which is highly reliable with respect to address reproduction in a reproduction operation.

1. An error correcting scheme, wherein when an error correcting code includes twenty data bits, seven parity bits as a burst error correction code for the data bits and five parity bits as a random error correction code for the data bits, the number of burst error correction bits of the burst error correction code is three and the number of random error correction bits of the random error correction code is one, a combination of a syndrome of the burst error correction code and a syndrome of the random error correction code is unique to each of 1-bit errors, 2-bit errors and 3-bit burst error and error correction is performed based on the syndrome of the burst error correction code and the syndrome of the random error correction code.

2. A disk medium comprising a sector group including a plurality of positionally continuous sectors in which address information including at least address data and parity data is dispersedly provided in the plurality of sectors of the sector group in a prescribed unit, the address information including an information sequence described by a combination of at least 0, land an identification mark, the identification mark being provided at the head of the sector group, the address data including data bits, and the parity data including parity bits.

3. A disk medium according to claim 1, wherein a length of the sector group is shorter than one track length.

4. A disk medium according to claims 2 or 3, wherein an integral number of the sector groups are set so as to be a unit of information to be recorded or reproduced.

5. A disk medium according to any one of claims 2-4, wherein the address information is dispersedly provided in the plurality of sectors of the sector group by one code alphabet.

6. A disk medium according to any one of claims 2-5, wherein in the address information, the address data is positioned so as to follow the identification mark and the address data includes a LSB.

7. A disk medium according to any one of claims 2-5, wherein in the address information, the parity data is positioned so as to follow the identification mark, the address data is positioned after the parity data, and the address data includes the LSB.

8. A disk medium according to any one of claims 2-7, wherein the disk medium has a capacity of 235 bytes or lower, one sector includes 211 byte-data, the sector group includes thirty two sectors, and the address information is configured so as to include a 1-bit identification mark, 19-bit address data, 7-bit parity data of the burst error correction code for the address data, and 5-bit parity data of the random error correction code for the address data.

9. A disk medium according to any one of claims 2-7, wherein the disk medium has a capacity of 236 bytes or lower, one sector includes 211 byte-data, the sector group includes thirty two sectors, the address information is configured so as to include a 1-bit identification mark, 19-bit address data, 7-bit parity data of the burst error correction code for the address data, and 5-bit parity data of the random error correction code for the address data, and the 1-bit identification mark can be selected from two types of identification marks.

10. A disk reproducing method, wherein in the disk medium according to any one of claims 3-9, after reproducing address information of a prescribed and specific sector group, a track jump over one track is performed so as to reproduce the address information of the prescribed and specific sector group from the lead thereof.

11. A disk reproducing method, wherein in the disk medium according to any one of claims 2-9, detection of the identification mark starts acquisition of the address information.

12. A disk recording method, wherein in the disk medium according to any one of claims 4-9, detection of the identification mark starts a data recording operation or data reproducing operation.

13. A disk reproducing method, wherein in the disk medium according to any one of claims 4-9, detection of the identification mark starts a data recording operation or data reproduction operation.

14. A disk recording method, wherein in the disk medium according to any one of claims 2-9, error detection or error correction is performed on reproduced address information and a recording/reproducing operation is performed on the sector group represented by the address information based on a result of the error detection or error correction.

15. A disk reproducing method, wherein in the disk medium according to any one of claims 2-9, error detection or error correction is performed on reproduced address information and a recording/reproducing operation is performed on the sector group represented by the address information based on a result of the error detection or error correction.

16. A disk reproducing method, wherein in the disk medium according to any one of claims 2-9, when it is detected that a size of an envelope of a reproduced signal representing bits in reproduced address information are not in a prescribed range or it is detected, based on the reproduced signal representing the bits in the address information, that relative positions of a head and a track are not in a prescribed range, reproduced data bits corresponding to the bits in the reproduced address information can be used as erasure bits so as to perform an erasure correction.

17. A disk recording method, wherein in the disk medium according to any one of claims 2-9, burst error correction is performed on reproduced data of the address information.

18. A disk reproducing method, wherein in the disk medium according to any one of claims 2-9, burst error correction is performed on reproduced data of the address information.

19. A disk recording method, wherein in the disk medium according to any one of claims 2-9, random error correction is performed on reproduced data of the address information.

20. A disk reproducing method, wherein in the disk medium according to any one of claims 2-9, random error correction is performed on reproduced data of the address information.

21. A disk recording method, wherein in the disk medium according to any one of claims 2-9, burst error correction or random error correction is performed on reproduced data of the address information.

22. A disk reproducing method, wherein in the disk medium according to any one of claims 2-9, burst error correction or random error correction is performed on reproduced data of the address information.

23. A disk recording method, wherein in the disk medium according to any one of claims 6 or 7, a part of the address information is reproduced so as to detect that a sector group being reproduced is not an expected sector group.

24. A disk reproducing method, wherein in the disk medium according to any one of claims 6 or 7, a part of the address information is reproduced so as to detect that a sector group being reproduced is not an expected sector group.
